(19) United States
(12) Patent Application Publication
(10) Pub. No.: US 2019/0312186 A1
(43) Pub. Date: Oct. 10, 2019

(54) Side-Emitting LED with Increased Illumination

(71) Applicant: Microsoft Technology Licensing, LLC, Redmond, WA (US)

(72) Inventor: Patrick Robert DOYLE, San Francisco, CA (US)

(21) Appl. No.: 15/948,660

(22) Filed: Apr. 9, 2018

(51) Int. Cl. H01L 33/60; H01L 33/48; F21V 8/00; G02B 27/00

(52) U.S. Cl. CPC H01L 33/60; H01L 33/486; G02B 6/0073; H01L 2933/0016; H01L 2933/0066; H01L 2933/0058; G02B 27/0093

(57) ABSTRACT

A light source includes a side-emitting, light emitting diode (LED) that is mounted on a printed circuit board (PCB) or other substrate. The LED is used to illuminate a target such as a sensor or the like. In order to increase the amount of illumination emitted by the LED that reaches the target, a reflector is located on the PCB. The reflector receives light that is emitted by the LED and directed toward the PCB and not the target. This light, which would otherwise be lost, is reflected by the reflector and re-directed toward the target. By reducing the amount of light is lost, the amount of light reaching the target can be increased without a commensurate increase in the current supplied to the LED.

### BACKGROUND

Light emitting diodes (LEDs) are a class of photonic semiconductor devices that convert an applied voltage into light by causing electron-hole recombination events in an appropriate semiconductor material. In turn, some or all of the energy released in the recombination event produces a photon. LEDs are available for operation across visible, ultraviolet (UV) and infrared (IR) wavelengths. Light emitting diodes are increasingly being used for illumination purposes, as opposed to simply being used as a self-luminous object (e.g., as an indicator light on a piece of electronic equipment). LEDs used for illumination purposes, however, tend to require higher amounts of light output than do LEDs that are used as indicators. Normally, to ensure that an LED may be seen by a sensor, the system will simply drive a higher current through the LED to increase its output illumination.

### SUMMARY

In embodiments, a light source includes a side-emitting, light emitting diode (LED) that is mounted on a printed circuit board (PCB) or other substrate. The LED is used to illuminate a target such as a sensor or the like. In order to increase the amount of illumination emitted by the LED that reaches the target, a reflector is located on the PCB. The reflector receives light that is emitted by the LED and directed toward the PCB and not the target. This light, which would otherwise be lost, is reflected by the reflector and re-directed toward the target. By reducing the amount of light is lost, the amount of light reaching the target can be increased without a commensurate increase in the current supplied to the LED.

In certain embodiments the reflector may be fabricated from the same materials that are used to form the metallization (e.g., traces and electrode pads) elements on the PCB. In this way the reflector may be fabricated at the same time as the metallization elements. For instance, in some embodiments the metallization elements and the reflector may be from a bilayer material that includes a highly conductive material such as copper and a surface finishing material such as electroless nickel immersion gold (ENIG).

In certain embodiments, the side-emitting LED may emit light at infrared (IR) wavelengths. These embodiments may be particularly suitable for use with a reflector having a surface layer formed from ENIG, since ENIG reflects significantly at IR wavelengths.

In certain embodiments, the light source emitting light at IR wavelengths is employed in an eye tracking system. In these embodiments the IR light illuminates a user's eye and a sensor or other target observes reflected glints and iris movements. In some particular embodiments, the eye tracking system may be used in a see through, mixed reality display device.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. Furthermore, the claimed subject matter is not limited to implementations that solve any or all disadvantages noted in any part of this disclosure. These and various other features will be apparent from a reading of the following Detailed Description and a review of the associated drawings.

### BRIEF DESCRIPTION OF THE DRAWINGS

FIG. 1 is a perspective view of one example of a light source that includes a surface mounted, side-emitting light-emitting diode (LED).

FIG. 2 is an exploded perspective view of the side-emitting LED and the substrate shown in FIG. 1.

FIG. 3 shows an elevational side view of the side-emitting LED mounted on a substrate.

FIG. 4 shows an elevational side view of another example of a side-emitting LED mounted on substrate in which a reflector is located on the substrate.

FIG. 5 shows a perspective view of one example of a printed circuit board (PCB) showing an anode pad, cathode pad and a pad for a reflector.

FIG. 6 shows a graph of the illumination profile from the light source in a direction orthogonal to the emission surface of the LED.

FIG. 7 is a flowchart showing a simplified example of a method of forming a PCB on which a side-emitting LED may be mounted and which includes a reflector for reflecting light emitted by the LED.

FIG. 8 is a block diagram depicting example components of one example of a see-through, mixed reality display device system.

FIG. 9 is a side view of an eyeglass temple of the frame of the see-through, mixed reality display device system.

FIG. 10 is a top view of an example of the display optical system of the see-through, mixed reality display device system.

Like reference numerals indicate like elements in the drawings. Elements are not drawn to scale unless otherwise indicated.

### DETAILED DESCRIPTION

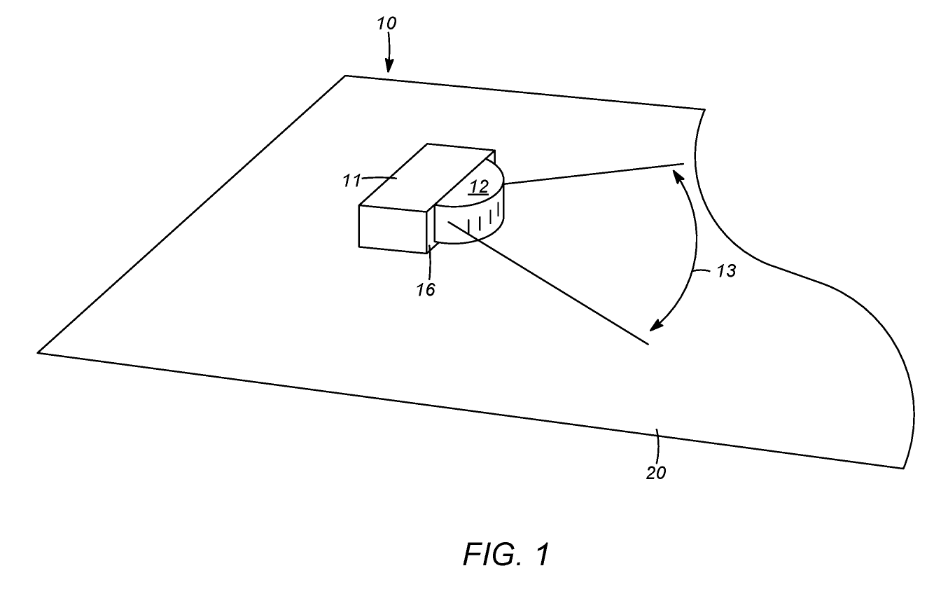

FIG. 1 is a perspective view of a light source 10 that includes a surface mounted, side-emitting light-emitting diode (LED) 11 that is mounted on a substrate 20 such a rigid or flexible printed circuit board (PCB). The side-emitting LED 11 includes an encapsulated semiconductor chip or die conductively affixed to a metallic substrate. In one embodiment the LED 11 produces an output at infrared wavelengths (e.g. 700 nm-1 mm). More generally, the LED 11 may produce an output at any selected wavelength(s) in the visible, ultraviolet (UV) and/or infrared (IR) bands. By way of illustration, the semiconductor chip incorporated in the LED 11 may be constructed, for example, from Ga—Al—As, GaAlS, SiC, GaP, GaAsP, or InGaS.

The side-emitting LED 11 may be optionally molded with an optical element 12 formed as part of, or attached to, the emitting surface 16 of the LED. The optical element 12 is generally of a size and shape to cause the illumination to exit the optical element 12 at a pre-determined fan angle 13 relative to the substrate 20. The fan angle 13 extends in a plane that is generally parallel to the substrate 13 and is typically wider than the emission angle in the transverse plane. In one embodiment the optical element 12 may be a diffusing lens to facilitate distribution of the light through the fan angle 13.

It should also be understood that the term LED does not limit the physical and/or electrical package type of an LED. For example, an LED may refer to a single light emitting device having multiple dies that are configured to respectively emit different spectra of radiation. Also, an LED may be associated with a phosphor that is considered as an integral part of the LED (e.g., some types of white LEDs). In general, the term LED may refer to packaged LEDs, non-packaged LEDs, surface mount LEDs, chip-on-board LEDs, T-package mount LEDs, radial package LEDs, power package LEDs, LEDs including some type of encasement. LED 11 can comprise any size and/or shape. LED 11 can be substantially square, rectangular, regular, irregular, or asymmetrical in shape. In some aspects, LED 11 can, for example, comprise a footprint where at least one side measures approximately 4 mm or less. In general, any dimension of LED chip 11 is contemplated.

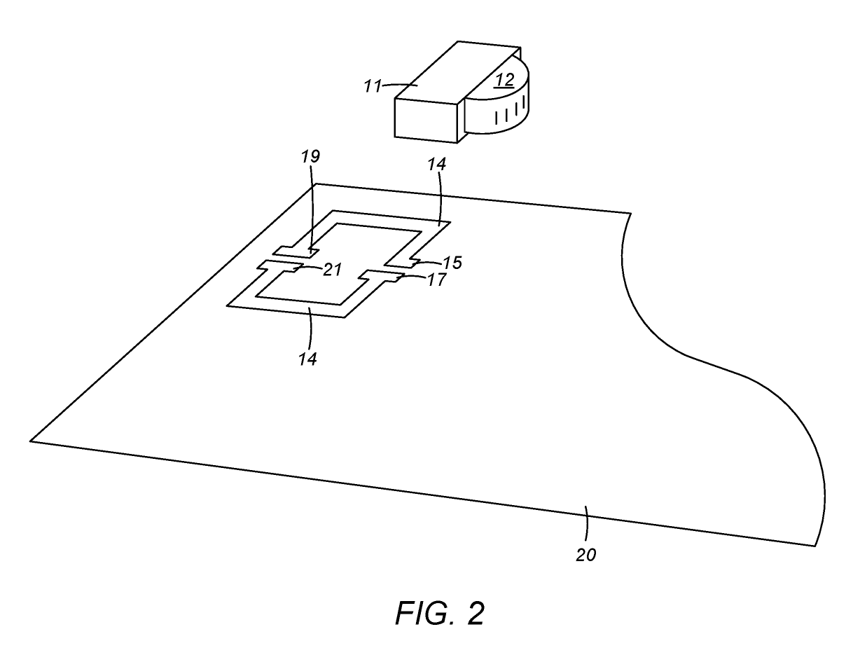

FIG. 2 is an exploded perspective view of the LED 11 and the substrate 20 illustrating a metal trace 14 that is formed on the substrate 20. The metal trace 14 defines metal pads 15 and 17 for the bottom anode and cathode electrodes of the LED 11. Also shown are optional metal pads 19 and 21 that may be employed for an optional electronic device that may also be located on the substrate, such as a transient voltage suppressor, for example. The LED 11 may be secured to the substrate 20 using surface mount technology techniques. In this way the bottom anode and cathode of the LED 11 are mechanically and electrically connected to the substrate 20. In some cases the bottom electrodes of the LED 11 are directly mounted on the metal pads 15 and 17. In other embodiments the LED 11 first may be mounted on a submount to simplify handling of the LED die.

While the example shown in FIGS. 1 and 2 employ a surface mounted LED, in other embodiments other LED types, such as those with bonding wires may be employed, for instance. In the case of bonding wires, the anode and cathode leads of the LED will extend into through-holes located on the substrate in order to establish electrical and mechanical connections.

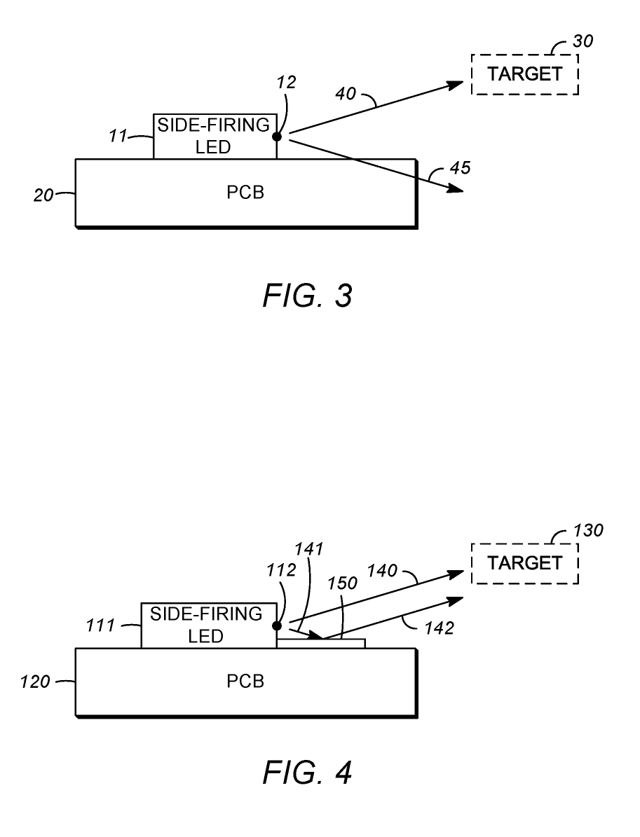

FIG. 3 shows an elevational side view of the side-emitting LED 11 mounted on substrate 20. Also shown is a target 30 such as a sensor or the like that is to receive illumination from the LED 11. Two light rays 40 and 45 are shown being emitted by the LED 11. As shown one of the light rays 40 is incident upon the target 30. The other light ray 46, however, is directed downward into the substrate 20 and hence is not available for detection by the target. It may be understood that terms of orientation such as “up or upward,” “down or downward” “direction,” “horizontal,” and “vertical” are used primarily to establish relative orientations in the illustrative examples shown and described herein for ease of description and are not to be construed to limit the scope of the various configurations shown herein.

As previously mentioned, the LED 11 is often driven at higher currents to maximize the amount of illumination received by the target 30. However, the amount of current needed to provide the target 30 with a given amount of illumination can be reduced if at least some of the radiation reflected downward to the substrate 20 could be instead directed to the target 30.

FIG. 4 shows an elevational side view of a side-emitting LED 111 mounted on substrate 120 that is similar to the arrangement shown in FIG. 3, except that in FIG. 4 a reflector 150 is located on the substrate 120 at a position that allows it to intercept some of the downwardly directed illumination emitted by the LED 111 through optical element 112. This downwardly directed illumination, represented in FIG. 4 by light ray 141, is reflected by the reflector 150 as reflected light ray 142 so that it is redirected to the target 130, along with the line-of-sight light ray 140. By properly positioning the reflector 150 on the substrate 120 relative to the LED 111, the amount of illumination that can be directed to the target 130 can be significantly increased (by upwards of a factor of two) over the arrangement shown in FIG. 3, which does not employ a reflector.

The reflector 150 may be formed of any suitable material that is able to reflect a significant portion of the light that is emitted by the LED 111. In embodiments in which the substrate 120 is a rigid or flexible PCB, the reflector 150 may be formed from a material that is compatible with the manufacturing steps that are employed to fabricate the metal traces and pads located on the PCB. For instance, the reflector 150 may be formed from the same material as the metal pads. That is, the reflector 150 may be formed in the same manner as the metal pad, but which in the final device will remain exposed to receive incident illumination emitted by the LED since there is no electrical component mounted onto it.

The metal traces and pads on a PCB are commonly formed from copper, which is coated or plated with a material that prevents the copper from oxidizing and which provides a suitable solderable surface that allows a good solder joint to be established. Finishing materials that are often used to coat or plate the metal traces and pads include electroless nickel immersion gold (ENIG), which include an electroless nickel plating covered with a thin layer of immersion gold. Other finishing materials that may be employed to coat or plate the metal traces and pads include, without limitation, electroless nickel autocatalytic gold (ENAG), electroless nickel electroless palladium immersion gold (ENEPIG), electroless nickel immersion palladium immersion gold (ENPIG), immersion tin plating, and organic solderability preservative (OSP). Any of these materials may serve as the reflector 150, provided they have a sufficient reflectivity at the wavelengths of light emitted by the LED 111.

For instance, ENIG or ENEPIG may be particularly suitable for use with LEDs that emit infrared energy since these materials reflect a significantly greater fraction of incident infrared radiation compared to copper. Moreover, these materials also provide a smooth surface for highly spectral reflection, thereby maximizing the direct reflection of the light rays and minimizing scattering.

One advantage that arises from the use of any of the aforementioned coating or plating materials is that the reflector 150 will be automatically formed by defining and fabricating the reflector during the metal trace and pad design and fabrication process just like any other metal pad on the PCB, since it will be automatically be coated or plated during the fabrication process. Hence, the reflector 150 may be formed without adding or modifying any additional manufacturing steps to the process.

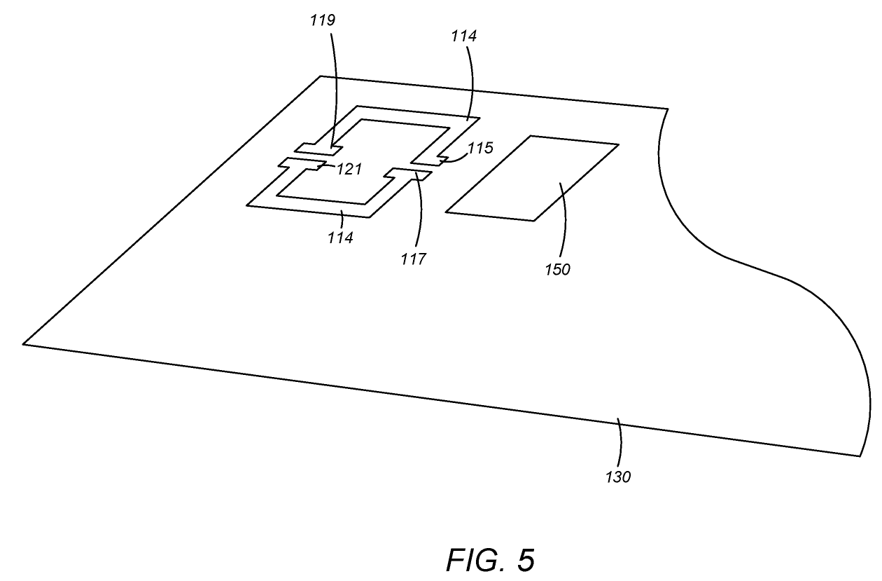

FIG. 5 shows a perspective view of one example of a PCB 130 similar to the PCB shown in FIG. 2 with the anode pad 115, cathode pad 117 and the reflector 150 that is formed from yet another metal pad. Also shown is the metal traces 114 extending from the anode and cathode pads, respectively. As previously mentioned, in one embodiment all the pads and traces may be made from a common material or materials such as copper coated ENIG, which can all be formed during the same fabrication steps. The reflector 150 may be grounded or it may have a floating potential. That is, in some embodiments the reflector 150 may be isolated without being connected to any other metals such any metal traces, vias, etc.

As shown in FIG. 5, in some embodiments the surface area encompassed by the reflector 150 may be greater than the surface area encompassed by either of the anode or cathode pads 115 and 117. In this way the available surface area of the reflector 150 can be maximized to ensure that the maximum amount of illumination is received by the reflector 150 and directed to the target. For instance, in one embodiment, the surface area of the reflector 150 may be at least 2 times, and in some cases at least three times, greater than the surface area of either the anode or cathode pad. For instance, if the dimensions of the LED are about 4×4 mm, then in one embodiment the dimensions of the reflector 150 may be about 2 mm×1 mm. In general, however, the geometry and location of the reflector may be adapted to the particular application in which the LED is to be employed and will depend on various factors such as the dimensions of the LED, the location and dimensions of the target, and the amount of illumination that is required to be received by the target from the LED.

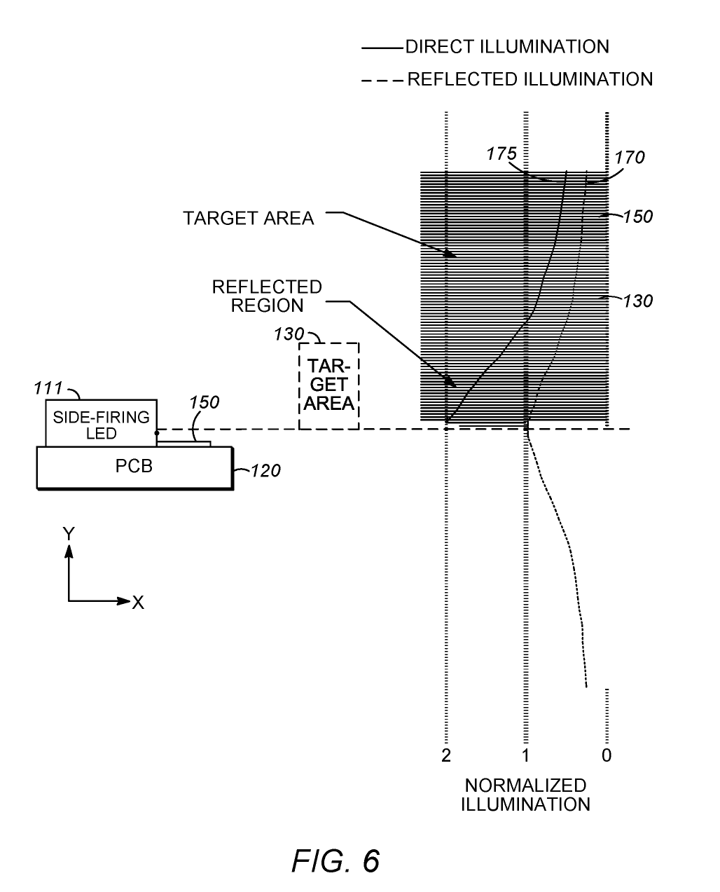

FIG. 6 shows a graph of the illumination profile in a direction orthogonal to the emission surface of the LED 111 (i.e., the y-direction in FIG. 6). The graph shows the profile 170 of the direct illumination emitted by the LED 111, which is normalized to a value of 1 at the point on the profile 170 where the maximum illumination is received. Also shown on the graph is the profile 175 of the direct illumination plus the reflected illumination. It should be noted that the reflected illumination falls to zero at points along the y-axis below the reflector 150 surface and hence makes no contribution to the illumination received by the target 130. Superimposed on the graph of FIG. 6 is a plan view of both the target 130 and reflector 150 to illustrate the increased amount of illumination that is directed to the target as a result of the reflected illumination.

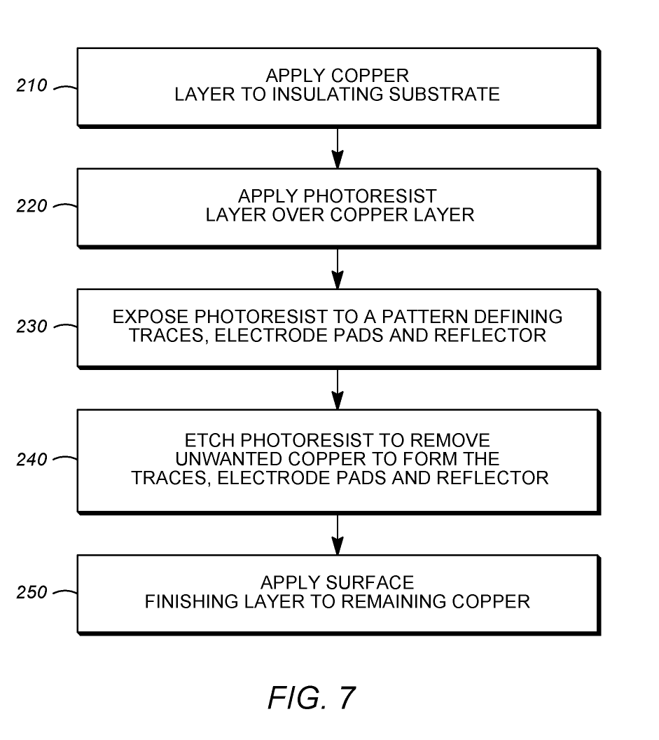

FIG. 7 is a flowchart showing a simplified example of a method of forming a PCB on which a side-emitting LED may be mounted and which includes a reflector for reflecting light emitted by the LED. First, at block 210 an insulating substrate is provided with a thin copper or other conductive metal) layer deposited across the top surface. Next, the metal is patterned by any of a variety of processes such as a photolithography process, which begins by applying a photoresist layer over metal layer at block 220. The photoresist may be a positive or negative photoresist. At block 230 a mask is placed over the photoresist and exposed to a pre-defined pattern of light (typically UV light) that defines the traces and pads. The pads that are defined in this manner includes anode and cathode pads for the electrodes of the LED and an additional pad for the reflector. Next, at block 240 the unwanted metal is removed by an etching process. A surface finishing layer is then applied over the remaining metal at block 250.

As previously mentioned, in one embodiment the light source described herein may employ a side-emitting LED that emits light at IR wavelengths. Such a light source may be used in a variety of applications. For example, it may be employed as a flash for an IR camera. In another example, the light source may be employed as an IR light source for an eye tracking system that may be incorporated, for instance, in a see-through, mixed reality display device system that enables a user to observe digital information overlaid on the physical scenery. Typically, the eye tracker includes an IR light source to illuminate the user's eye and a camera to image the user's eye, e.g., to observe the reflected glints and iris movements for calculation of a gaze direction.

For purposes of illustration one example of a see-through, mixed reality display device that incorporates an eye tracking system with the IR light source illustrated herein will be described below.

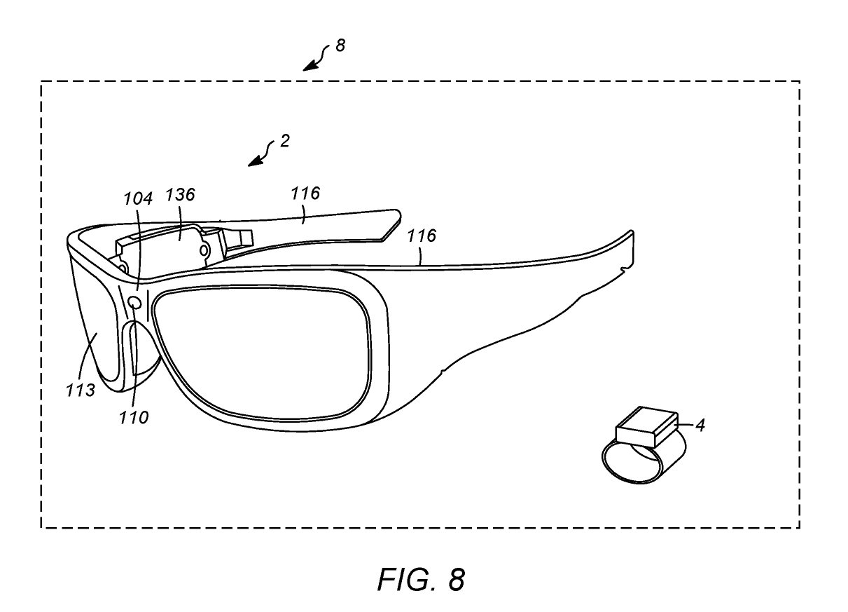

FIG. 8 is a block diagram depicting example components of one example of a see-through, mixed reality display device system. System 8 includes a see-through display device as a near-eye, head mounted display device 2 in communication with processing unit 4 (e.g., a smart phone, tablet or laptop computer) via a wire or a wireless protocol. The processing unit 4 may include much of the computing power used to operate near-eye display device 2. Head mounted display device 2, which in one example is in the shape of eyeglasses in a frame 116, is worn on the head of a user so that the user can see through a display, embodied in this example as a display optical system 113 for each eye, and thereby have an actual direct view of the space in front of the user.

Frame 116 provides a support for holding elements of the system in place as well as a conduit for electrical connections. The frame 116 includes a temple or side arm for resting on each of a user's ears. Temple includes control circuitry 136 for the display device 2. Nose bridge 104 of the frame 116 includes a microphone 110 for recording sounds and transmitting audio data to processing unit 4.

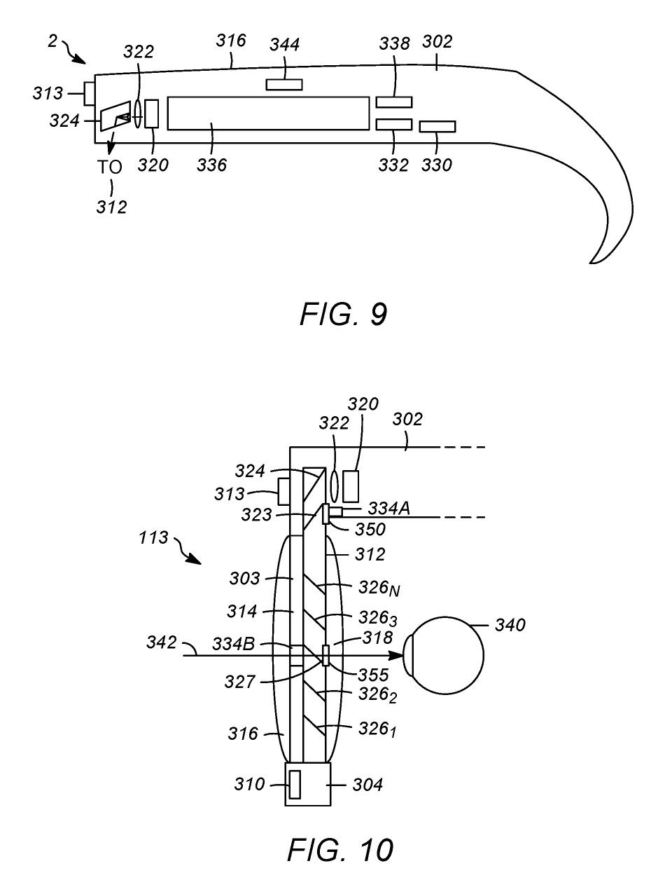

FIG. 9 is a side view of an eyeglass temple 302 of the frame 316. At the front of frame 316 is a physical environment facing or outward facing video camera 313 that can capture video and still images which are transmitted to the processing unit 4. Control circuits 336 provide various electronics that support the other components of head mounted display device 2. Inside, or mounted to the temple 302, are ear phones 330, inertial sensors 332, GPS transceiver 344 and temperature sensor 338. The inertial sensors are for sensing position, orientation, and sudden accelerations of the head mounted display device 2. From these movements, head position may be determined.

Mounted to or inside the temple 302 is an image generation unit 320 that includes a micro display 320 for projecting images of one or more virtual objects and lens system 322 for directing images from micro display 320 into a see-through planar waveguide 312. A reflecting element 324 receives the images directed by the lens system 322 and optically couples the image data into the planar waveguide 312.

FIG. 10 is a top view of an example of the display optical system 113 of the see-through, mixed reality device. A portion of the frame 315 of the near-eye display device 2 will surround a display optical system 113 for providing support for one or more optical elements. In order to show the components of the display optical system 113, in this case for the right eye system, in the head mounted display device 2, a portion of the frame 115 surrounding the display optical system is not depicted.

In this example the display optical system 113 includes a planar waveguide 312, an optional opacity filter 314, see-through lens 316 and see-through lens 318. In one embodiment, opacity filter 314 is behind and aligned with see-through lens 316, planar waveguide 312 is behind and aligned with opacity filter 314, and see-through lens 318 is behind and aligned with planar waveguide 312. See-through lenses 316 and 318 may be standard lenses used in eye glasses and can be made to any prescription (including no prescription). Opacity filter 314, which is aligned with planar waveguide 312, selectively blocks natural light, either uniformly or on a per-pixel basis, from passing through planar waveguide 312 in order to enhance the contrast of the virtual imagery.

The planar waveguide 312 transmits visible light from micro display 320 to the eye 340 of the user wearing head mounted display device 2. The see-through planar waveguide 312 also allows visible light from in front of the head mounted display device 2 to be transmitted through itself to eye 140, as depicted by arrow 342 representing an optical axis of the display optical system 113, thereby allowing the user to have an actual direct view of the space in front of head mounted display device 2 in addition to receiving a virtual image from the micro display 320. Thus, the walls of planar waveguide 312 are see-through. Planar waveguide 312 includes a first reflecting surface 324 (e.g., a mirror or other surface). Visible light from micro display 320 passes through lens 322 and becomes incident on reflecting surface 324. The reflecting surface 324 reflects the incident visible light from the micro display 320 such that visible light is trapped inside a planar, substrate comprising planar waveguide 312 by internal reflection.

Infrared illumination and reflections also traverse the planar waveguide 312 for an eye tracking system 334 for tracking the position of the user's eyes. A user's eyes will be directed at a subset of the environment which is the user's area of focus or gaze. The eye tracking system 334 comprises an eye tracking illumination source 334A, which in this example is mounted to or inside the temple 302, and an eye tracking IR sensor 334B, which is this example is mounted to or inside a brow 303 of the frame 316. The eye tracking IR sensor 334B can alternatively be positioned between lens 318 and the temple 302. It is also possible that both the eye tracking illumination source 334A and the eye tracking IR sensor 334B are mounted to or inside the brow 303 of the frame 316.

The technology allows flexibility in the placement of entry and exit optical couplings (which can also be referred to as input- and output-couplers) to and from the waveguide's optical path for the image generation unit 320, the illumination source 334A and the eye tracking IR sensor 334B. The visible illumination representing images and the infrared illumination may enter from any direction about the waveguide 312, and one or more wavelength selective filters (e.g. 327) direct the illumination out of the waveguide centered about the optical axis 342 of the display optical system 113.

The eye tracking illumination source 334A may include the side-emitting IR light source described herein and shown, for example, in FIG. 4. The target (e.g., target 130 shown in FIG. 4) may be the user's pupil or, alternatively, any of the intermediate optical elements such as the wavelength selective filter 323, which in turn direct the IR light onto the user's pupil. The spatial location and orientation of the side-emitting IR light source and the location, size and orientation of the LED and the reflector on the substrate of the side-emitting IR light source may be arranged so that both the direct and reflected IR illumination from the side-emitting IR light source are applied to the target. Since reflected illumination that would otherwise be lost is received by the target, the power requirements of the side-emitting IR light source may be reduced, which is particularly advantageous in a portable, lightweight device such as a mixed reality display device.

The wavelength selective filter 323 transmits visible spectrum light from the micro display 320 via reflecting surface 324 and directs the infrared wavelength illumination from the eye tracking illumination source 334A into the planar waveguide 112 where the IR illumination is internally reflected within the waveguide until reaching another wavelength selective filter 327 aligned with the optical axis 342. From the IR reflections, the position of the pupil within the eye socket can be identified by known imaging techniques when the eye tracking IR sensor 334B is an IR camera, and by glint position data when the eye tracking IR sensor 334B is a type of position sensitive detector (PSD). The use of other types of eye tracking IR sensors and other techniques for eye tracking are also possible.

Various exemplary embodiments of the present display system are now presented by way of illustration and not as an exhaustive list of all embodiments. An example includes a light emitting diode (LED) source, comprising: a substrate; a side-emitting LED mechanically and electrically secured to the substrate; and a reflector located on substrate, the reflector being configured to receive illumination emitted by an emitting surface of the LED so that at least a portion of the illumination is directed to a target to be illuminated.

In another example, the substrate is a printed circuit board (PCB). In another example, the PCB includes metal anode and cathode pads and a reflector. The LED may be surface mounted to the anode and cathode pads to establish electrical and mechanical contact between an anode electrode and the anode pad and a cathode electrode and the cathode pad. In another example, the anode and cathode pads and the reflector are formed from a common material having a surface layer that is able to reflect light at wavelengths emitted by the LED. In another example, the anode and cathode pads and the reflector include a metal layer coated with a protective and specularly reflective solderable surface layer. In another example, the protective and specularly reflective solderable surface layer includes electroless nickel immersion gold (ENIG). In another example, the LED is configured to emit infrared illumination. In another example, the reflector has a surface area greater than a surface area of the anode pad or the cathode pad. In another example, the reflector is located adjacent to the LED on the PCB such that direct illumination and reflected illumination from the reflector is incident on a target.

A further example includes a method of forming an LED light source, comprising: patterning a metal layer on a printed circuit board (PCB) with a predefined circuit pattern, the circuit pattern including at least first and second metal electrode pads for respectively receiving an anode and cathode electrode of a surface mounted, side-emitting LED, the circuit pattern further including a third metal pad configured to receive illumination emitted by an emitting surface of the LED so that at least a portion of the illumination reflected by the third metal pad is directed to a target to be illuminated; coating the patterned metal layer with a solderable finishing surface material, the solderable finishing surface material reflecting light at wavelengths emitted by the LED; and soldering the LED to PCB so that the anode and the cathode electrodes of the LED are mechanically and electrically secured to the first and second metal electrode pads, respectively, while the third metal pad remains exposed to receive illumination from the LED.

Yet another example includes an apparatus for use in tracking an eye that is illuminated by infrared light, comprising: a transparent planar waveguide that includes an input coupler and an output coupler that are spatially separated from one another; a light source adapted to illuminate the transparent planar waveguide with infrared light so that a portion of the incident infrared light travels through the transparent planar waveguide and is incident upon the output coupler so that the infrared light is reflected out of the transparent planar waveguide, wherein the light source includes: a substrate; a side-emitting infrared LED mechanically and electrically secured to the substrate; and a reflector located on substrate, the reflector being configured to receive infrared light emitted by an emitting surface of the LED so that at least a portion of the infrared light is directed to a target on or in the transparent planar waveguide.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A light emitting diode (LED) source, comprising:
a substrate;
a side-emitting LED mechanically and electrically secured to the substrate; and
a reflector located on substrate, the reflector being configured to receive illumination emitted by an emitting surface of the LED so that at least a portion of the illumination is directed to a target to be illuminated, wherein the reflector has a surface area greater than a surface area of an anode pad or a cathode pad disposed on the substrate.

2. The LED source of claim 1 wherein the substrate is a printed circuit board (PCB).

3. The LED source of claim 2 wherein the PCB includes metal anode and cathode pads and a reflector, the LED being surface mounted to the anode and cathode pads to establish electrical and mechanical contact between an anode electrode and the anode pad and a cathode electrode and the cathode pad, the anode and cathode pads and the reflector being formed from a common material having a surface layer that is able to reflect light at wavelengths emitted by the LED.

4. The LED source of claim 3 wherein the anode and cathode pads and the reflector include a metal layer coated with a protective and specularly reflective solderable surface layer.

5. The LED source of claim 4 wherein the protective and specularly reflective solderable surface layer includes electroless nickel immersion gold (ENIG).

6. The LED source of claim 5 wherein the LED is configured to emit infrared illumination.

7. (canceled)

8. The LED source of claim 1 wherein the reflector is located adjacent to the LED on the PCB such that direct illumination and reflected illumination from the reflector is incident on a target.

9. A method of forming an LED light source, comprising:
patterning a metal layer on a printed circuit board (PCB) with a predefined circuit pattern, the circuit pattern including at least first and second metal electrode pads for respectively receiving an anode and cathode electrode of a surface mounted, side-emitting LED, the circuit pattern further including a third metal pad configured to receive illumination emitted by an emitting surface of the LED so that at least a portion of the illumination reflected by the third metal pad is directed to a target to be illuminated;
coating the patterned metal layer with a solderable finishing surface material, the solderable finishing surface material reflecting light at wavelengths emitted by the LED;
soldering the LED to PCB so that the anode and the cathode electrodes of the LED are mechanically and electrically secured to the first and second metal electrode pads, respectively, while the third metal pad remains exposed to receive illumination from the LED.

10. The method of claim 9 wherein the protective and specularly reflective solderable surface layer includes electroless nickel immersion gold (ENIG).

11. The method of claim 10 wherein the LED is configured to emit infrared illumination.

12. The method of claim 9 wherein the reflector has a surface area greater than a surface area of the anode pad or the cathode pad.

13. The method of claim 9 wherein the reflector is located adjacent to the LED on the PCB such that direct illumination and reflected illumination from the reflector is incident on a target.

14. An apparatus for use in tracking an eye that is illuminated by infrared light, comprising:
a transparent planar waveguide that includes an input coupler and an output coupler that are spatially separated from one another;
a light source adapted to illuminate the transparent planar waveguide with infrared light so that a portion of the incident infrared light travels through the transparent planar waveguide and is incident upon the output coupler so that the infrared light is reflected out of the transparent planar waveguide, wherein the light source includes:
a substrate;
a side-emitting infrared LED mechanically and electrically secured to the substrate; and
a reflector located on substrate, the reflector being configured to receive infrared light emitted by an emitting surface of the LED so that at least a portion of the infrared light is directed to a target on or in the transparent planar waveguide, wherein the reflector has a surface area greater than a surface area of an anode pad or a cathode pad disposed on the substrate.

15. The apparatus of claim 14 wherein the substrate is a printed circuit board (PCB).

16. The apparatus of claim 15 wherein the PCB includes metal anode and cathode pads and a reflector, the LED being surface mounted to the anode and cathode pads to establish electrical and mechanical contact between an anode electrode and the anode pad and a cathode electrode and the cathode pad, the anode and cathode pads and the reflector being formed from a common material having a surface layer that is able to reflect light at wavelengths emitted by the LED.

17. The apparatus of claim 16 wherein the anode and cathode pads and the reflector include a metal layer coated with a protective and specularly reflective solderable surface layer.

18. (canceled)

19. The apparatus of claim 14 wherein the reflector is located adjacent to the LED on the PCB such that direct illumination and reflected illumination from the reflector is incident on a target.

20. The apparatus of claim 14 wherein a surface of the reflector is coated with an electroless nickel immersion gold (ENIG) layer.
